(19) United States
(12) Patent Application Publication
(10) Pub. No.: US 2025/0031452 A1
(43) Pub. Date: Jan. 23, 2025

(54) DISPLAY DEVICE AND DISPLAY DRIVING CIRCUIT DEVICE

(71) Applicant: E Ink Holdings Inc., Hsinchu (TW)

(72) Inventors: Chun Hsien Chao, Hsinchu (TW); Kuo-Hsing Cheng, Hsinchu (TW); Wen-Chung Tang, Hsinchu (TW); Wen-Yu Kuo, Hsinchu (TW)

(73) Assignee: E Ink Holdings Inc., Hsinchu (TW)

(21) Appl. No.: 18/765,310

(22) Filed: Jul. 7, 2024

(30) Foreign Application Priority Data
Jul. 21, 2023 (TW) 112127344

(51) Int. Cl. H01L 27/12

(52) U.S. Cl. CPC H01L 27/124

(57) ABSTRACT

A display device, including a pixel array substrate, a display layer, and a driving circuit, is provided. The pixel array substrate includes a support plate, a pixel circuit array disposed on a first surface of the support plate, first and second transmission pillars, and first and second transmission lines disposed on a second surface of the support plate. The first transmission pillars are located between the pixel circuit array and a first edge of the support plate. The second transmission pillars are located between the pixel circuit array and a second edge of the support plate. The first transmission lines are respectively connected to the first transmission pillars. The second transmission lines are respectively connected to the second transmission pillars. The display layer overlaps with the first and second transmission lines. The first transmission lines and the second transmission lines are electrically connected to the driving circuit.

### CROSS-REFERENCE TO RELATED APPLICATION

This application claims the priority benefit of Taiwan application serial no. 112127344, filed on Jul. 21, 2023. The entirety of the above-mentioned patent application is hereby incorporated by reference herein and made a part of this specification.

### BACKGROUND

### Technical Field

The disclosure relates to an electronic product, and in particular to a display device and a display driving circuit device.

### Description of Related Art

Enlarging the display area and reducing the frame width have always been the focus of the development of the display device. However, the conventional design often needs to reserve enough area in the frame area to dispose peripheral routing and/or driving circuits, so the width of the frame cannot be effectively reduced.

### SUMMARY

The disclosure provides a display device and a display driving circuit device having a narrow frame design.

A display device of the disclosure includes a pixel array substrate, a display layer, and a driving circuit. The pixel array substrate includes a support plate, a pixel circuit array, multiple first transmission pillars, multiple second transmission pillars, multiple first transmission lines, and multiple second transmission lines. The support plate has a first surface and a second surface opposite to each other. The pixel circuit array is disposed on the first surface of the support plate. The first transmission pillars are located between the pixel circuit array and a first edge of the support plate, and each continuously extends from the first surface to the second surface. The first transmission pillars are arranged along a row direction to form a row of first transmission pillar. The second transmission pillars are located between the pixel circuit array and a second edge of the support plate, and each continuously extends from the first surface to the second surface. The second transmission pillars are arranged along the row direction to form a row of second transmission pillar, and the first transmission pillars of the row of first transmission pillars and the second transmission pillars in the row of second transmission pillars are alternately arranged in a direction intersected with the row direction. The first transmission lines are disposed on the second surface of the support plate and are respectively connected to the first transmission pillars. The second transmission lines are disposed on the second surface of the support plate and are respectively connected to the second transmission pillars. The display layer is disposed on the pixel array substrate, and the display layer overlaps with the first transmission lines and the second transmission lines. The driving circuit is disposed on the pixel array substrate, and the first transmission lines and the second transmission lines are all electrically connected to the driving circuit. The pixel array substrate is located between the display layer and the driving circuit.

In an embodiment of the disclosure, the pixel circuit array includes multiple first signal lines, multiple second signal lines, multiple signal transmission lines, and multiple active elements. The first signal lines each extends along a first direction and are each connected to one of the first transmission pillars. The second signal lines each extends along a second direction and are each connected to one of the signal transmission lines. The signal transmission lines each extends along the first direction and are each connected to one of the second transmission pillars. The active elements are each connected to one of the first signal lines and one of the second signal lines. The first direction and the second direction intersect each other.

In an embodiment of the disclosure, the first signal lines transmit one of a scan signal and a data signal, and the second signal lines transmit other one of the scan signal and the data signal.

In an embodiment of the disclosure, the first direction is parallel to a direction from the first edge of the support plate to the second edge of the support plate.

In an embodiment of the disclosure, the first transmission line and the second transmission line are composed of a same conductive layer.

In an embodiment of the disclosure, the first transmission lines each has a first end and a second end. The first ends of the first transmission lines are connected to the first transmission pillars. The driving circuit is connected to the second ends of the first transmission lines.

In an embodiment of the disclosure, the first ends of the first transmission lines are arranged with a first pitch, the second ends of the first transmission lines are arranged with a second pitch, and the first pitch is greater than the second pitch.

In an embodiment of the disclosure, the second transmission lines each has a third end and a fourth end. The third ends of the second transmission lines are connected to the second transmission pillars, and the driving circuit is connected to the fourth ends of the second transmission lines.

In an embodiment of the disclosure, the third ends of the second transmission lines are arranged with a third pitch, the fourth ends of the second transmission lines are arranged with a fourth pitch, and the third pitch is greater than the fourth pitch.

In an embodiment of the disclosure, the fourth ends of the second transmission lines are disposed between the second ends of the first transmission lines to divide the second ends of the first transmission lines into two groups.

A display driving circuit device of the disclosure includes a pixel array substrate, a display layer, and a driving circuit. The pixel array substrate includes a support plate, having a first surface and a second surface opposite to each other; a pixel circuit array, disposed on the first surface of the support plate; multiple first transmission pillars, each extending continuously from the first surface to the second surface, wherein the first transmission pillars are arranged along a row direction to form a row of first transmission pillar; multiple second transmission pillars, each extending continuously from the first surface to the second surface, wherein the second transmission pillars are arranged along the row direction to form a row of second transmission pillar, and the first transmission pillars of the row of first transmission pillars and the second transmission pillars in the row of second transmission pillars are alternately arranged in a direction intersected with the row direction; multiple first transmission lines, disposed on the second surface of the support plate and respectively connected to the first transmission pillars; and multiple second transmission lines, disposed on the second surface of the support plate and respectively connected to the second transmission pillars. The driving circuit is disposed on the second surface of the support plate, and the first transmission lines and the second transmission lines are all electrically connected to the driving circuit. At least one of the first transmission lines and at least one of the second transmission lines are staggered with each other.

In an embodiment of the disclosure, the first transmission pillars and second transmission pillars are located between the pixel circuit array and a same edge of the support plate.

In an embodiment of the disclosure, the first transmission lines and the second transmission lines are of different conductive layers.

Based on the above, the display device and the display driving circuit device of the embodiments of the disclosure use the transmission pillars penetrating the support plate to connect the signal lines and the transmission lines located on opposite surfaces, so that the transmission lines and the driving circuit may be disposed on the surface opposite to the signal lines. Therefore, the peripheral area of the display device does not need to reserve the layout area of the transmission lines and the driving circuit, and can have an extremely narrow frame.

### BRIEF DESCRIPTION OF THE DRAWINGS

FIG. 1 is a schematic view of a display device according to an embodiment of the disclosure.

FIG. 2 is a schematic view of a front side of a pixel array substrate according to an embodiment of the disclosure.

FIG. 3 is a schematic view of a rear side of a pixel array substrate according to an embodiment of the disclosure.

FIG. 4 is a schematic layout view of transmission lines disposed on a rear side in a display device according to an embodiment of the disclosure.

FIG. 5 is a schematic partial cross-sectional view of a pixel array substrate in a display device according to an embodiment of the disclosure.

FIG. 6 is a schematic view of a front side of a pixel array substrate according to an embodiment of the disclosure.

FIG. 7 is a schematic view of a rear side of a pixel array substrate according to an embodiment of the disclosure.

### DESCRIPTION OF THE EMBODIMENTS

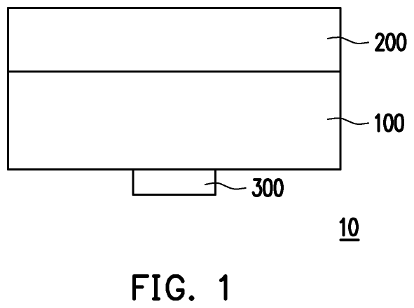

FIG. 1 is a schematic view of a display device according to an embodiment of the disclosure. A display device 10 includes a pixel array substrate 100, a display layer 200, and a driving circuit 300. The display layer 200 is disposed on the pixel array substrate 100, the driving circuit 300 is disposed on the pixel array substrate 100, and the pixel array substrate 100 is located between the display layer 200 and the driving circuit 300. In some embodiments, the pixel array substrate 100 may have a pixel circuit structure to provide a driving electric field to drive the display layer 200. In some embodiments, the display layer 200 includes an electronic paper layer, which has, for example, a microcup or microcapsule structure encapsulating an electrophoretic display material, but not limited thereto. In some embodiments, the driving circuit 300 may be a packaged semiconductor chip. In other embodiments, the driving circuit 300 may also be a driving circuit directly made on glass (support plate), such as a gate on array (GOA) circuit. In some embodiments, the display device 10 may further include a cover plate covering the display layer 200 to provide functions such as protection and blocking water vapor.

The display device 10 may adopt reflective display technology and may reflect external light or a front light source located between the user and the display layer 200 to display an image. In some embodiments, the display light of the display device 10 may not pass through the pixel array substrate 100. In some embodiments, the display layer 200 may be regarded as being disposed on a front side of the pixel array substrate 100, and the driving circuit 300 may be regarded as being disposed on a rear side of the pixel array substrate 100, wherein the user is located at the front side to view the image. The driving circuit 300 and the display layer 200 are stacked on each other in the thickness direction, but the display image provided by the display layer 200 is not blocked or affected by the driving circuit 300.

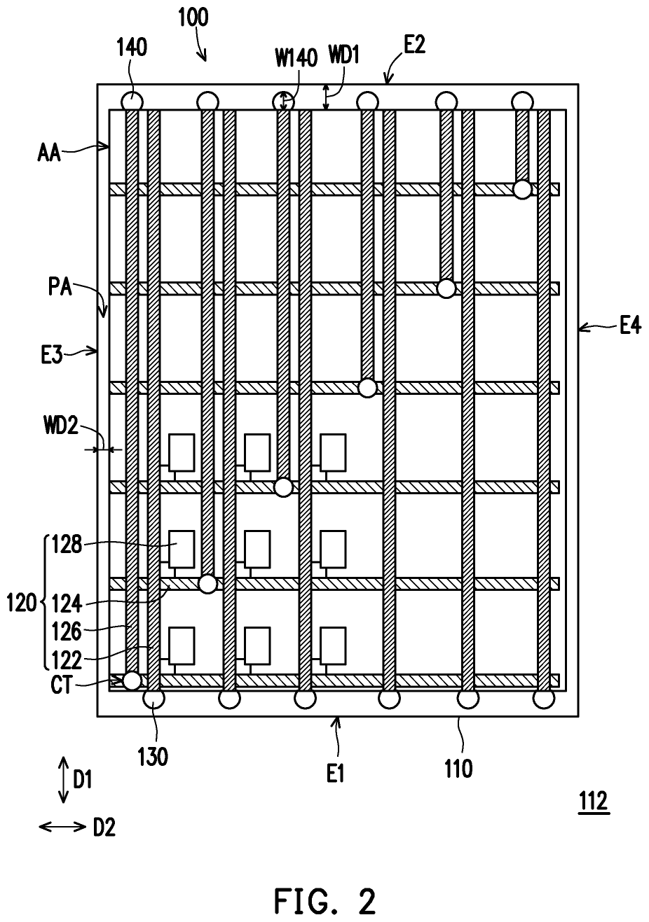

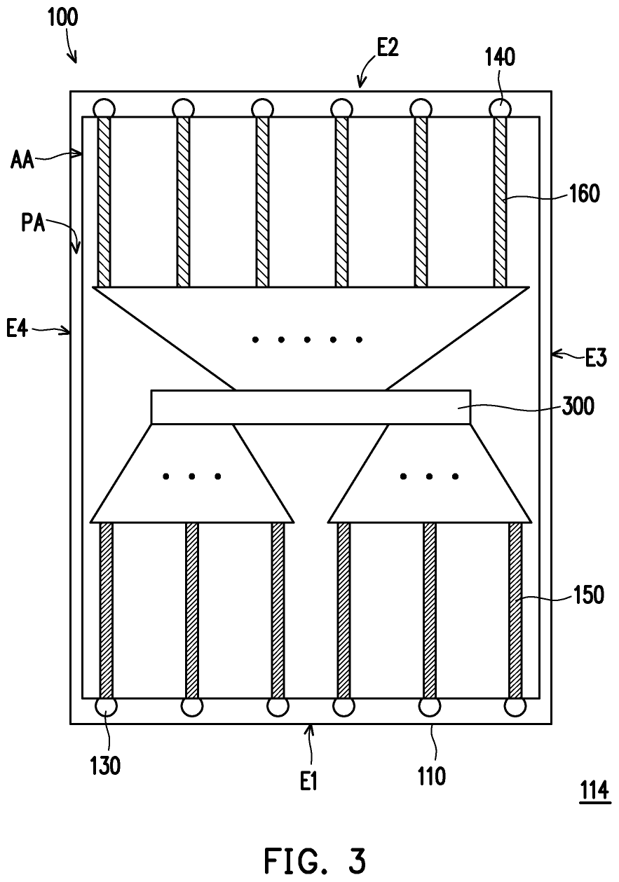

FIG. 2 is a schematic view of a front side of a pixel array substrate according to an embodiment of the disclosure, and FIG. 3 is a schematic view of a rear side of a pixel array substrate according to an embodiment of the disclosure. Please refer to FIG. 2 and FIG. 3 at the same time. The pixel array substrate 100 includes a support plate 110, a pixel circuit array 120, multiple first transmission pillars 130, multiple second transmission pillars 140, multiple first transmission lines 150, and multiple second transmission lines 160. The first transmission pillars 130 and the second transmission pillars 140 may each penetrate the support plate 110 and be electrically connected to the pixel circuit array 120. In FIG. 3, the first transmission lines 150 may be each connected between one of the first transmission pillars 130 and the driving circuit 300, and the second transmission lines 160 may be each connected between one of the second transmission pillars 140 and the driving circuit 300. In other words, the first transmission lines 150 and the second transmission lines 160 are all electrically connected to the driving circuit 300, and the first transmission pillars 130, the second transmission pillars 140, the first transmission lines 150, and the second transmission lines 160 are used to establish electrical transmission between the pixel circuit array 120 and the driving circuit 300. In some embodiments, the driving circuit 300, the first transmission lines 150 and the second transmission lines 160 may overlap with a display area AA of the display device 10 (that is, overlap with the display layer 200), and a peripheral area PA of the display device 10 may be very narrow. Here, the display area AA may be an area defined by the outline of the display layer 200 (shown in FIG. 1), and the peripheral area PA may be edges of the display area AA to edges (a first edge E1, a second edge E2, a third edge E3, and a fourth edge E4) of the support plate 110, but not limited thereto.

The support plate 110 has a first surface 112 and a second surface 114 opposite to each other, wherein FIG. 2 shows the first surface 112 of the support plate 110 and components disposed thereon. FIG. 3 shows the second surface 114 of the support plate 110 and components disposed thereon. The support plate 110 is a plate having sufficient mechanical support. The support plate 110 is, for example, a glass plate, a plastic plate, etc. In some embodiments, the support plate 110 may be light transmissive, but may also be selectively a non-light-transmissive plate.

The support plate 110 has a rectangular shape and includes the first edge E1, the second edge E2, the third edge E3, and the fourth edge E4. The first edge E1 is opposite to the second edge E2 in a first direction D1, and the third edge E3 is opposite to the fourth edge E4 in a second direction D2. In the embodiment, the first direction D1 is substantially parallel to a direction from the first edge E1 of the support plate 110 to the second edge E2 of the support plate 110, and the second direction D2 is substantially parallel to a direction from the third edge E3 of the support plate 110 to the fourth edge E4 of the support plate 110.

The pixel circuit array 120 is disposed on the first surface 112 of the support plate 110. In FIG. 2, the pixel circuit array 120 may include multiple first signal lines 122, multiple second signal lines 124, multiple signal transmission lines 126, and multiple active elements 128. The first signal lines 122 each extends along the first direction D1 and are each connected to one of the first transmission pillars 130. The second signal lines 124 each extends along the second direction D2 and are each connected to a corresponding signal transmission line 126. The signal transmission lines 126 each extends along the first direction D1 and are each connected to a corresponding second transmission pillar 140. The active elements 128 are each connected to a corresponding one of the first signal lines 122 and a corresponding one of the second signal lines 124. The first direction D1 and the second direction D2 may intersect each other, such as being orthogonal, but not limited thereto.

In some embodiments, the first signal lines 122 transmit one of a scan signal and a data signal, and the second signal lines 124 transmit the other one of the scan signal and the data signal. For example, the first signal line 122 is a scan line and the second signal line 124 is a data line or the first signal line 122 is a data line and the second signal line 124 is a scan line. In some embodiments, the pixel circuit array 120 may also include a capacitor connected to the individual active element 128. In some embodiments, the pixel circuit array 120 may further include a touch element, a sensing element, an image capturing element, a vibration element, or other elements for providing individual functions.

In the embodiment, the first signal line 122 extends along the first direction D1 to the corresponding first transmission pillar 130 and may be then electrically connected to the first transmission line 150 on the second surface 114 through the first transmission pillar 130. Therefore, the first signal line 122 need not extend beyond the first transmission pillar 130. The signal transmission line 126 extends along the first direction D1 to the corresponding second transmission pillar 140 and may be then electrically connected to the second transmission line 160 on the second surface 114 through the second transmission pillar 140. Therefore, the second signal line 124 need not extend beyond the second transmission pillar 140. As shown in FIG. 2, the first transmission pillar 130 and the second transmission pillar 140 may be roughly located at the edge of the display area AA. In this way, the peripheral area PA between the display area AA and the first edge E1 of the support plate 110 and the peripheral area PA between the display area AA and the second edge E2 of the support plate 110 may be very narrow, which helps to achieve a narrow frame design in the first direction D1. In some embodiments, a width WD1 of the peripheral area PA between the display area AA and the first edge E1 (or the second edge E2) of the support plate 110 may be less than twice an individual horizontal dimension W140 of the first transmission pillar 130 and the second transmission pillar 140.

In the embodiment, the second signal line 124 extends along the second direction D2 and is connected to the active elements 128 arranged in the second direction D2. Meanwhile, each of the signal transmission lines 126 may be connected to one of the second signal lines 124 through a corresponding connection contact CT. Each signal transmission line 126 may extend between one of the connection contacts CT and one of the second transmission pillars 140. However, in some embodiments, the signal transmission line 126 may also selectively extend beyond the corresponding connection contact CT. In FIG. 1, two adjacent connection contacts CT are not on the same second signal line 124. The connection contacts CT are arranged along a diagonal path, but may be arranged along a V-shaped path or a zigzag path in other embodiments.

The second signal line 124 and the signal transmission line 126 connected through the connection contact CT may provide a T-shaped or L-shaped signal transmission path. Therefore, the second signal line 124 does not need to extend beyond the display area AA in the second direction D2 and may provide a narrow peripheral area PA in the second direction D2, thereby also implementing a narrow frame in the second direction D2. In some embodiments, a width WD2 of the peripheral area PA between the display area AA and the third edge E3 (or the fourth edge E4) of the support plate 110 in the second direction D2 may be less than the individual horizontal dimension W140 of the first transmission pillar 130 and the second transmission pillar 140.

In some embodiments, the pixel circuit array 120 may be composed of multiple conductive layers, multiple insulating layers, and at least one semiconductor layer. The first signal line 122 and the second signal line 124 may be composed of different conductive layers, and at least one insulating layer is disposed between the conductive layer of the first signal line 122 and the conductive layer of the second signal line 124. In this way, the first signal line 122 and the second signal line 124 may be staggered with each other without contact. In some embodiments, the signal transmission line 126 and the second signal line 124 may be composed of different conductive layers, at least one insulating layer is disposed between the conductive layer of the signal transmission line 126 and the conductive layer of the second signal line 124, and the connection contact CT may penetrate the at least one insulating layer, so that the signal transmission line 126 may be in electrical contact with the second signal line 124. In some embodiments, the conductive layer of the signal transmission line 126 and the conductive layer of the first signal line 122 may be selected to be the same conductive layer or different conductive layers.

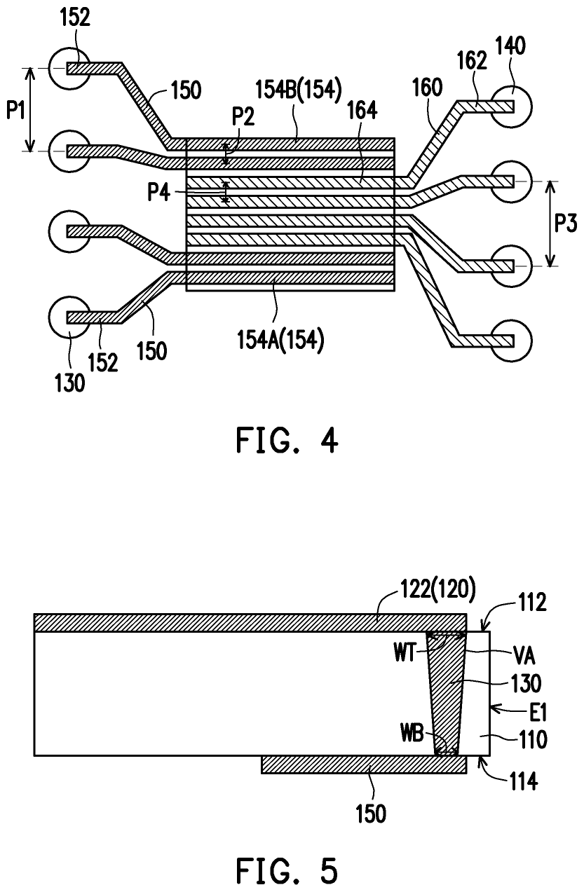

FIG. 4 is a schematic layout view of transmission lines disposed on a rear side in a display device according to an embodiment of the disclosure. Please refer to FIG. 3 and FIG. 4 at the same time. The first transmission lines 150 each has a first end 152 and a second end 154. The first ends 152 of the first transmission lines 150 are respectively connected to the first transmission pillars 130, and the driving circuit 300 is connected to the second ends 154 of the first transmission lines 150. Similarly, the second transmission lines 160 each has a third end 162 and a fourth end 164. The third ends 162 of the second transmission lines 160 are respectively connected to the second transmission pillars 140, and the driving circuit 300 is connected to the fourth ends 164 of the second transmission lines 160.

In response to the dimensions of the driving circuit 300, the first ends 152 of the first transmission lines 150 are arranged at a first pitch P1, the second ends 154 of the first transmission lines 150 are arranged at a second pitch P2, and the first pitch P1 is greater than the second pitch P2. Similarly, the third ends 162 of the second transmission lines 160 are arranged at a third pitch P3, the fourth ends 164 of the second transmission lines 160 are arranged at a fourth pitch P4, and the third pitch P3 is greater than the fourth pitch P4.

In some embodiments, the fourth ends 164 of the second transmission lines 160 are disposed between the second ends 154 of the first transmission lines 150 to divide the second ends 154 of the first transmission lines 150 into two groups, that is, a second end 154A and a second end 154B. The second end 154A and the second end 154B are respectively located on two opposite sides of the fourth end 164. In some embodiments, the numbers of the second end 154A and the second end 154B are the same, but not limited thereto.

In some embodiments, the wiring paths of the first transmission lines 150 and the second transmission lines 160 do not overlap or are not staggered. The first transmission line 150 and the second transmission line 160 may be composed of the same conductive layer. The first transmission line 150 and the second transmission line 160 are substantially disposed on the same plane. In some embodiments, the first transmission line 150 and the second transmission line 160 may be manufactured on the second surface 114 of the support plate 110 by deposition together with lithography. In some embodiments, the first transmission line 150 and the second transmission line 160 may be manufactured on the second surface 114 of the support plate 110 by printing.

FIG. 5 is a schematic partial cross-sectional view of a pixel array substrate in a display device according to an embodiment of the disclosure. The schematic cross-sectional view of FIG. 5 is used to understand structures of transmission members and may be used as a possible implementation of the first transmission pillar 130 and the second transmission pillar 140 in FIG. 2, and some components are omitted. In FIG. 5, the support plate 110 has the first surface 112 and the second surface 114 opposite to each other. The first signal line 122 of the pixel array 120 is disposed on the first surface 112, and the first transmission line 150 is disposed on the second surface 114. The support plate 110 has a via VA, and the via VA, for example, penetrates the entire thickness of the support plate 110. A metal material filled in the via VA constitutes the first transmission pillar 130. Therefore, the first transmission pillar 130 is disposed in the via VA and continuously extends from the first surface 112 to the second surface 114. The first transmission pillar 130 has an end surface width WT on the first surface 112 and an end surface width WB on the second surface. The end surface width WT may be greater than the end surface width WB. In other embodiments, the end surface width WT may be less than or equal to the end surface width WB. The individual horizontal dimension W140 of the first transmission pillar 130 (or the second transmission pillar 140) in FIG. 2 may be understood as that the first transmission pillar 130 (or the second transmission pillar 140) has the end surface width WT on the first surface 112.

In addition, the first transmission pillar 130 is separated from the first edge E1 of the support plate 110 by a distance and is not exposed from the first edge E1. Therefore, the first transmission pillar 130 is embedded in the support plate 110 and is horizontally surrounded by the support plate 110. In some embodiments, the first transmission pillar 130 may have varying widths. For example, the two ends are wide and the middle is narrow or vice versa.

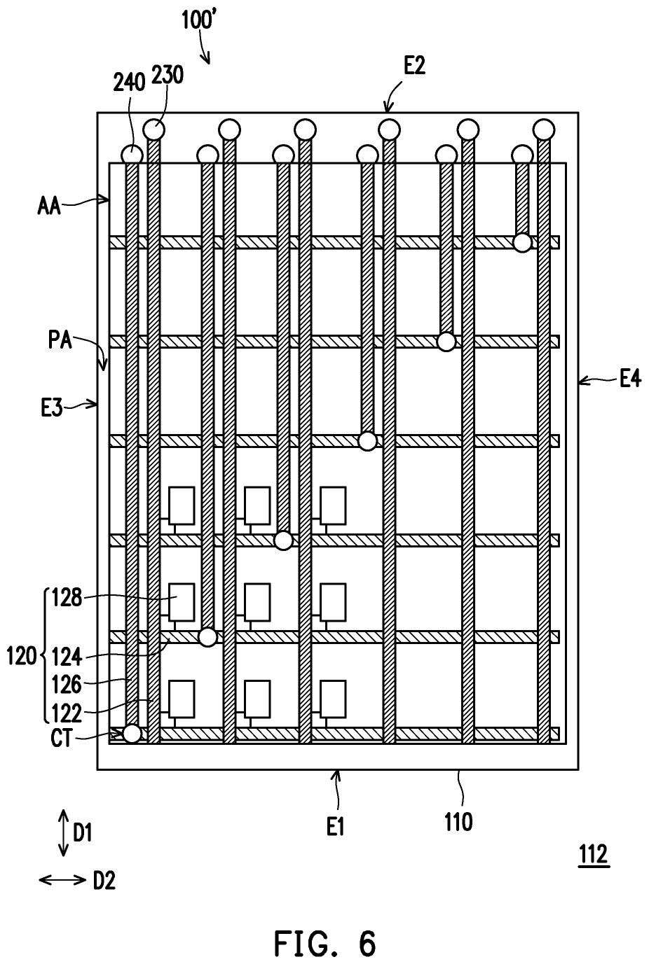

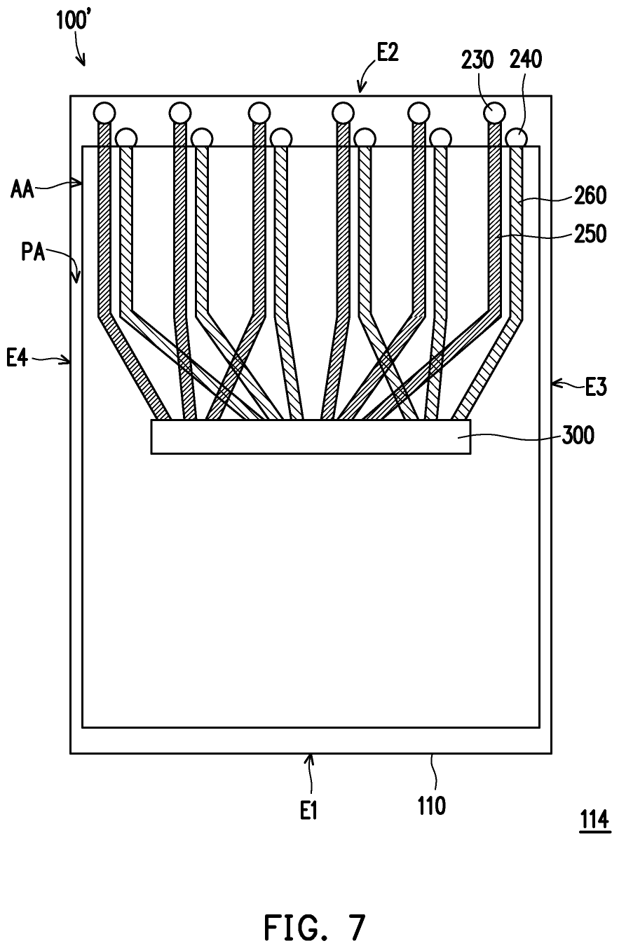

FIG. 6 is a schematic view of a front side of a pixel array substrate according to an embodiment of the disclosure, and FIG. 7 is a schematic view of a rear side of a pixel array substrate according to an embodiment of the disclosure. Please refer to FIG. 6 and FIG. 7 at the same time. A pixel array substrate 100′ includes a support plate 110, a pixel circuit array 120, multiple first transmission pillars 230, multiple second transmission pillars 240, multiple first transmission lines 250, and multiple second transmission lines 260, wherein the support plate 110 and the pixel circuit array 120 are substantially similar to the foregoing embodiment, so the support plate 110 and the pixel circuit array 120 may be understood with reference to the description of the foregoing embodiment. The support plate 110 has a first surface 112 and a second surface 114 opposite to each other, wherein FIG. 6 shows the first surface 112 of the support plate 110 and components disposed thereon. FIG. 7 shows the second surface 114 of the support plate 110 and components disposed thereon.

Similar to the foregoing embodiment, the pixel circuit array 120 may include multiple first signal lines 122, multiple second signal lines 124, multiple signal transmission lines 126, and multiple active elements 128. The first signal lines 122 each extends along a first direction D1 and are each connected to one of the first transmission pillars 230. The second signal lines 124 each extends along a second direction D2 and are each connected to a corresponding signal transmission line 126. The signal transmission lines 126 each extends along the first direction D1 and are each connected to a corresponding second transmission pillar 240. In the embodiment, the first transmission pillars 230 are arranged along a row direction to form a row of first transmission pillar 230 and the second transmission pillars 240 are arranged along the row direction to form a row of second transmission pillar 240. In addition, the first transmission pillars 230 of the row of first transmission pillars and the second transmission pillars 240 in the row of second transmission pillars are alternately arranged in a direction intersected with the row direction. In some embodiments, the row direction may be substantially parallel to the second direction D2 and the first transmission pillars 230 of the row of first transmission pillars and the second transmission pillars 240 in the row of second transmission pillars are alternately arranged in the first direction D1.

In the embodiment, the support plate 110 has a first edge E1, a second edge E2, a third edge E3, and a fourth edge E4, the pixel circuit array 120 disposed on the support plate 110 is located in a display area AA, and a peripheral area PA may be regarded as between the display area AA and the edges. The first transmission pillars 230 and the second transmission pillars 240 may each penetrate the support plate 110 and be electrically connected to the pixel circuit array 120. In addition, the first transmission pillars 230 and the second transmission pillars 240 are all located between the pixel circuit array 120 and the same edge (for example, the second edge E2) of the support plate 110, but not limited thereto. In addition, the first transmission pillars 230 and the second transmission pillars 240 may be staggered and need not be limited to be arranged on the same straight trajectory. One of the first transmission pillars 230 and the second transmission pillars 240 is closer to the edge of the support plate 110 than the other one. For example, the first transmission pillars 230 are closer to the second edge E2 of the support plate 110 than the second transmission pillars 240, but not limited thereto.

In FIG. 7, the first transmission lines 250 may each be connected between one of the first transmission pillars 230 and the driving circuit 300, and the second transmission lines 260 may each be connected to between one of the second transmission pillars 240 and the driving circuit 300. The first transmission pillars 230, the second transmission pillars 240, the first transmission lines 250, and the second transmission lines 260 are used to establish electrical transmission between the pixel circuit array 120 and the driving circuit 300. The first transmission line 250 and the second transmission line 260 are used to transmit different types of signals. In some embodiments, the driving circuit 300 may be designed to centralize contacts of the same type of signals. As shown in FIG. 7, in order to connect to corresponding contacts of the driving circuit 300, the second transmission line 260 extends, for example, toward a middle section of the driving circuit 300, and the first transmission line 250 extends, for example, toward an outer section of the driving circuit 300.

In the embodiment, at least one of the first transmission lines 250 and at least one of the second transmission lines 260 may be staggered with each other. Therefore, the first transmission lines 250 and the second transmission lines 260 may be of different conductive layers. In other words, in the embodiment, at least two conductive layers and an insulating layer sandwiched between the two conductive layers may be formed on the second surface 114, thereby implementing the required circuit connection layout.

In summary, in the display device and the display driving circuit device of the embodiments of the disclosure, the transmission pillars penetrating the support plate are disposed on the pixel array substrate and the transmission pillars are disposed on the two opposite sides of the display area to transmit signals of different signal lines. The display device may have a narrow frame width, and particularly the frame width of each edge may be quite narrow, thereby implementing the structure of an all-around narrow frame.

What is claimed is:

1. A display device, comprising:
a pixel array substrate, comprising:
a support plate, having a first surface and a second surface opposite to each other;
a pixel circuit array, disposed on the first surface of the support plate;
a plurality of first transmission pillars, located between the pixel circuit array and a first edge of the support plate, and the first transmission pillars each continuously extending from the first surface to the second surface, wherein the first transmission pillars are arranged along a row direction to form a row of first transmission pillar;
a plurality of second transmission pillars, located between the pixel circuit array and a second edge of the support plate, and the second transmission pillars each continuously extending from the first surface to the second surface, wherein the second transmission pillars are arranged along the row direction to form a row of second transmission pillar, and the first transmission pillars of the row of first transmission pillars and the second transmission pillars in the row of second transmission pillars are alternately arranged in a direction intersected with the row direction;
a plurality of first transmission lines, disposed on the second surface of the support plate and respectively connected to the first transmission pillars; and
a plurality of second transmission lines, disposed on the second surface of the support plate and respectively connected to the second transmission pillars;
a display layer, disposed on the pixel array substrate, and the display layer overlapping with the first transmission lines and the second transmission lines; and
a driving circuit, disposed on the pixel array substrate, and the first transmission lines and the second transmission lines being all electrically connected to the driving circuit, wherein the pixel array substrate is located between the display layer and the driving circuit.

2. The display device according to claim 1, wherein the pixel circuit array comprises a plurality of first signal lines, a plurality of second signal lines, a plurality of signal transmission lines, and a plurality of active elements, the first signal lines each extends along a first direction and are each connected to one of the first transmission pillars, the second signal lines each extends along a second direction and are each connected to one of the signal transmission lines, the signal transmission lines each extends along the first direction and are each connected to one of the second transmission pillars, the active elements are each connected to one of the first signal lines and one of the second signal lines, and the first direction and the second directions intersect each other.

3. The display device according to claim 2, wherein the first signal lines transmit one of a scan signal and a data signal, and the second signal lines transmit other one of the scan signal and the data signal.

4. The display device according to claim 2, wherein the first direction is parallel to a direction from the first edge of the support plate to the second edge of the support plate.

5. The display device according to claim 1, wherein the first transmission line and the second transmission line are composed of a same conductive layer.

6. The display device according to claim 1, wherein the first transmission lines each has a first end and a second end, the first ends of the first transmission lines are connected to the first transmission pillars, and the driving circuit is connected to the second ends of the first transmission lines.

7. The display device according to claim 6, wherein the first ends of the first transmission lines are arranged with a first pitch, the second ends of the first transmission lines are arranged with a second pitch, and the first pitch is greater than the second pitch.

8. The display device according to claim 6, wherein the second transmission lines each has a third end and a fourth end, the third ends of the second transmission lines are connected to the second transmission pillars, and the driving circuit is connected to the fourth ends of the second transmission lines.

9. The display device according to claim 8, wherein the third ends of the second transmission lines are arranged with a third pitch, the fourth ends of the second transmission lines are arranged with a fourth pitch, and the third pitch is greater than the fourth pitch.

10. The display device according to claim 8, wherein the fourth ends of the second transmission lines are disposed between the second ends of the first transmission lines to divide the second ends of the first transmission lines into two groups.

11. A display driving circuit device, comprising:
a pixel array substrate, comprising:
a support plate, having a first surface and a second surface opposite to each other;
a pixel circuit array, disposed on the first surface of the support plate;
a plurality of first transmission pillars, the first transmission pillars each continuously extending from the first surface to the second surface, wherein the first transmission pillars are arranged along a row direction to form a row of first transmission pillar;
a plurality of second transmission pillars, the second transmission pillars each continuously extending from the first surface to the second surface, wherein the second transmission pillars are arranged along the row direction to form a row of second transmission pillar, and the first transmission pillars of the row of first transmission pillars and the second transmission pillars in the row of second transmission pillars are alternately arranged in a direction intersected with the row direction;
a plurality of first transmission lines, disposed on the second surface of the support plate and respectively connected to the first transmission pillars; and
a plurality of second transmission lines, disposed on the second surface of the support plate and respectively connected to the second transmission pillars; and
a driving circuit, disposed on the second surface of the support plate, and the first transmission lines and the second transmission lines being all electrically connected to the driving circuit, wherein at least one of the first transmission lines and at least one of the second transmission lines are staggered with each other.

12. The display driving circuit device according to claim 11, wherein the first transmission pillars and the second transmission pillars are located between the pixel circuit array and a same edge of the support plate.

13. The display driving circuit device according to claim 11, wherein the first transmission lines and the second transmission lines are of different conductive layers.
